(19) United States
(12) Patent Application Publication
(10) Pub. No.: US 2022/0381848 A1
(43) Pub. Date: Dec. 1, 2022

(54) METHOD AND SYSTEM FOR DETECTING VEHICLE BATTERY CELL IMBALANCE

(71) Applicant: GUANGZHOU AUTOMOBILE GROUP CO., LTD., GUANGZHOU (CN)

(72) Inventors: DAO HOANG HO, MILPITAS, CA (US); YIZHEN ZHANG, SAN JOSE, CA (US); YONGGANG XU, LOS GATOS, CA (US)

(21) Appl. No.: 17/335,604

(22) Filed: Jun. 1, 2021

(51) Int. Cl. G01R 31/396; G01R 31/367; G01R 31/3835; G06N 20/20; H01M 10/42; H01M 10/48

(52) U.S. Cl. CPC G01R 31/396; G01R 31/367; G01R 31/3835; G06N 20/20; H01M 10/425; H01M 10/486; H01M 2220/20; H01M 2010/4271

(57) ABSTRACT

A method and a system for detecting vehicle battery cell imbalance are provided. The method includes: acquiring a plurality of raw vehicle data of a target vehicle type in a preset time period; grouping the plurality of raw vehicle data into a predefined number of bins based on the data type and the value range of raw vehicle data; determining an observed bin-level cell voltage imbalance of the bin based on the raw vehicle data in each bin; building machine learning model to predict bin-level cell voltage imbalance of each bin, based on bin parameters defined; determining a difference between observed bin-level cell voltage imbalance and predicted bin-level cell voltage imbalance of each bin, to obtain an unaccounted bin-level cell voltage imbalance; and determining whether there is a high risk of cell imbalance in a target vehicle based on a weighted average of unaccounted bin-level cell voltage imbalances.

### TECHNICAL FIELD

The present disclosure generally relates to a field of electric vehicles, and more particularly, to a method and a system for detecting vehicle battery cell voltage imbalance.

### BACKGROUND

An Electric Vehicle (EV) battery pack is a complex system. The performance of the battery pack has a crucial impact on the vehicle performance. With the development of EV technology, the battery pack is becoming larger and larger. A large capacity battery pack is usually composed of many small capacity cells. The power source for a battery pack is its cells, and the number of cells is usually optimized by the vehicle's design. EV car manufacturers have been steadily increasing the battery performance-mostly by increasing the number of cells in the pack and the energy density of cells. As EV batteries grow larger, there is a more urgent need to monitor the battery at both pack level and cell level. In the working process of the battery pack, due to the individual differences of the battery cells and environmental factors, it usually leads to cell voltage imbalance between the cells. When the cell voltage imbalance of the battery pack is high, it will not only affect the performance of the pack, but also reduce the service life of the battery pack. It may even easily cause serious vehicle failure, such as vehicle battery losing capacity or catching fire. Therefore, the imbalance detection of vehicle battery packs is an effective means to reduce battery failure and improve battery life.

### SUMMARY

A method and a system are provided for detecting vehicle battery cell voltage imbalance according to embodiments of the present disclosure. The technical solution is as below:

According to a first aspect of embodiments of the present disclosure, a method is provided for detecting vehicle battery cell voltage imbalance, comprising:

acquiring a plurality of raw vehicle data of a target vehicle type in a preset time period, wherein the raw vehicle data comprising vehicle parameters of various data types of the target vehicle type;

grouping the plurality of raw vehicle data into a predefined number of bins based on the data type and the value range of raw vehicle data;

determining an observed bin-level cell voltage imbalance of the bin, wherein the observed bin-level cell voltage imbalance is an average of all observed cell voltage imbalances in the bin, and the observed cell voltage imbalance is a difference between the maximum battery cell voltage and the minimum battery cell voltage in a battery pack of the target vehicle type;

building a machine learning model to predict bin-level cell voltage imbalance of each bin, based on the bin parameters defined;

determining a difference between the observed bin-level cell voltage imbalance and the predicted bin-level cell voltage imbalance of each bin, to obtain an unaccounted bin-level cell voltage imbalance; and

determining whether there is high risk of cell imbalance in a target vehicle based on a weighted average of the plurality of unaccounted bin-level cell voltage imbalances.

According to a second aspect of embodiments of the present disclosure, a system for detecting vehicle battery cell voltage imbalance is provided, deployed in a vehicle or a cloud server, comprising a memory and a processor;

wherein the memory is configured to store computer-readable instructions;

wherein the processor is configured to read the computer-readable instructions stored in the memory to execute steps in a method for detecting vehicle battery cell imbalance;

wherein the method comprises:

acquiring a plurality of raw vehicle data of a target vehicle type in a preset time period, wherein the raw vehicle data comprising vehicle parameters of various data types of the target vehicle type;

grouping the plurality of raw vehicle data into a predefined number of bins based on the data type and the value range of raw vehicle data;

determining an observed bin-level cell voltage imbalance of the bin, wherein the observed bin-level cell voltage imbalance is an average of all observed cell voltage imbalances in the bin, and the observed cell voltage imbalance is a difference between the maximum battery cell voltage and the minimum battery cell voltage in a battery pack of the target vehicle type;

building a machine learning model to predict bin-level cell voltage imbalance of each bin, based on the bin parameters defined;

determining a difference between the observed bin-level cell voltage imbalance and the predicted bin-level cell voltage imbalance of each bin, to obtain an unaccounted bin-level cell voltage imbalance; and

determining whether there is a high risk of cell imbalance in a target vehicle based on a weighted average of the plurality of unaccounted bin-level cell voltage imbalances.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments consistent with the invention and, together with the description, serve to explain the principles of the invention.

FIG. 1 is a diagram of an application environment of a technical solution of one embodiment of the disclosure.

FIG. 2 is a flow diagram of a method for detecting vehicle battery cell imbalance in one embodiment of the disclosure.

FIG. 3A is a SOC data distribution diagram of a vehicle type in the charging state in one embodiment of the disclosure.

FIG. 3B is a diagram of a relationship between observed bin-level cell voltage imbalances and SOC in the charging state for one vehicle type in one embodiment of the disclosure.

FIG. 3C is a SOC data distribution diagram of a vehicle type in the driving state in one embodiment of the disclosure.

FIG. 3D is a diagram of a relationship between observed bin-level cell voltage imbalances and SOC of one vehicle type in the driving state in one embodiment of the disclosure.

FIG. 4A is a diagram of a relationship between machine learning model residues and SOC for charging state in one embodiment of the disclosure.

FIG. 4B is a diagram of a relationship between machine learning model residues and vehicle voltage for charging state in one embodiment of the disclosure.

FIG. 4C is a diagram of a relationship between machine learning model residues and vehicle current for charging state in one embodiment of the disclosure.

FIG. 4D is a diagram of a relationship between machine learning model residues and battery temperature average for charging state in one embodiment of the disclosure.

FIG. 5 is a machine learning model residues distribution diagram for charging state in one embodiment of the disclosure.

FIG. 6A is a diagram of a relationship between observed bin-level cell voltage imbalances, unaccounted bin-level cell voltage imbalances and SOC of one normal vehicle example in the state of charge and drive in one embodiment of the disclosure.

FIG. 6B is a diagram of a relationship between observed bin-level cell voltage imbalances, unaccounted bin-level cell voltage imbalances and vehicle current of the same normal vehicle example in the state of charge and drive in one embodiment of the disclosure.

FIG. 6C is a diagram of a relationship between observed bin-level cell voltage imbalances, unaccounted bin-level cell voltage imbalances and battery pack temperature average of the same normal vehicle example in the state of charge and drive in one embodiment of the disclosure.

FIG. 7 is a flow diagram of constructing an unaccounted cell voltage imbalances variation curve in an embodiment of the present disclosure.

FIG. 8 is a diagram of a change relationship between daily weighted average and time of one normal vehicle example in one embodiment of the disclosure.

FIG. 9A is a diagram of a relationship between observed bin-level cell voltage imbalances, unaccounted bin-level cell voltage imbalances and SOC of one high risk vehicle example in another embodiment of the disclosure.

FIG. 9B is a diagram of a change relationship between daily weighted average and time of the same high risk vehicle example in another embodiment of the disclosure.

FIG. 10 is a diagram of observed and unaccounted cell voltage imbalances variation curves and time in one embodiment of the present disclosure.

FIG. 11 is a flow diagram of further steps of determining whether there is high risk of cell imbalance in a target vehicle based on a weighted average of the plurality of unaccounted bin-level cell voltage imbalances in an embodiment of the disclosure.

FIG. 12 is a block diagram of a device for detecting vehicle battery cell imbalance in one embodiment of the disclosure.

FIG. 13 is a diagram of an electronic device in one embodiment of the disclosure.

### DETAILED DESCRIPTION

An example embodiment will now be described more fully with reference to the accompanying drawings. However, the example embodiments can be implemented in a variety of forms and should not be understood as being limited to the examples set forth herein; On the contrary, providing these example embodiments makes the description of the present disclosure more comprehensive and complete, and fully conveys the concept of the example embodiments to those skilled in the art. The attached drawings are only schematic diagrams of the present disclosure and are not necessarily drawn to scale. The same reference numerals in the figure denote the same or similar parts, and thus repeated description of them will be omitted.

In addition, the described features, structures or features may be incorporated in one or more example embodiments in any suitable manner. In the following description, many specific details are provided to give a full understanding of the exemplary embodiments of the present disclosure. However, those skilled in the art will realize that one or more of the specific details can be omitted by practicing the technical solution of the disclosure, or other methods, components, steps, etc. can be adopted. In other cases, well-known structures, methods, implementations or operations are not shown or described in detail to avoid confusing aspects of the present disclosure.

Some block diagrams shown in the figures are functional entities and do not necessarily correspond to physically or logically independent entities. These functional entities may be implemented in the form of software, or in one or more hardware modules or integrated circuits, or in different networks and/or processor devices and/or microcontroller devices.

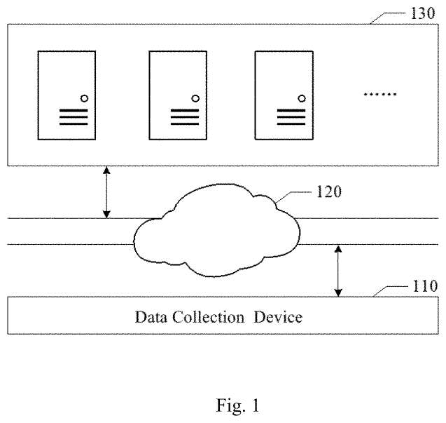

FIG. 1 is a diagram of an application environment of a technical solution of an embodiment of the disclosure.

According to the diagram of the real-time environment of the disclosure, as shown in FIG. 1, the embodiment environment includes a data collection device 110, a network 120 and a computer device 130. The data collection device 110 may be a data acquisition device, which is installed inside or outside a vehicle, such as a sensor device installed inside the vehicle. The network 120 may be a communication medium of various connection types capable of providing a communication link between the detection device 110 and the computer device 130. For example, it may be a wired communication link or a wireless communication link, such as a vehicle CAN bus communication. The computer device 130 may be a server, a server cluster or the like with computing power and it is not limited here.

The data collection device 110 is configured to collect raw data of a target vehicle type. For example, the data collection device 110 includes various types of sensors installed around a battery pack of the target vehicle. During the operation of the target vehicle, various types of data of the battery pack is collected to obtain the raw vehicle data, and then the raw vehicle data from multiple vehicles is sent to computer device 130 via network 120.

The computer device 130 may be an on-board or cloud based control system, which obtains the raw vehicle data from the data collection device 110, processes and calculates the raw vehicle data to determine whether the target vehicle has the high risk of battery cell imbalance. In this way, the risk detection of the cell imbalance of the target vehicle type can be realized in the application environment including the data collection device 110, the network 120 and the computer device 130, and then the vehicle fault caused by the cell imbalance can be detected and addressed early.

The following describes in detail the method for detecting vehicle battery cell imbalance provided by the disclosure in combination with the specific embodiments.

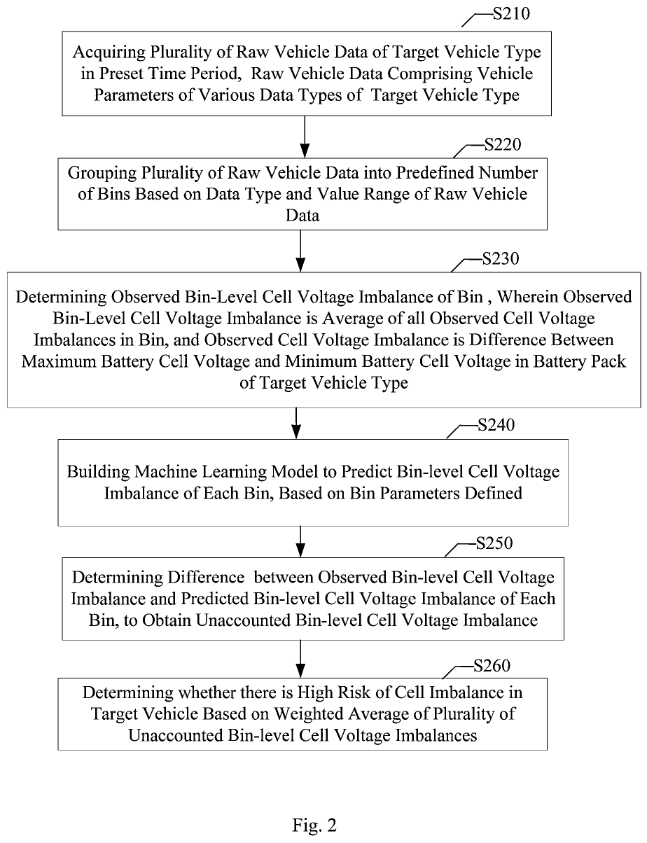

Referring to FIG. 2, FIG. 2 is a flow diagram of a method for detecting vehicle battery cell imbalance in one embodiment of the disclosure. The method for detecting vehicle battery cell imbalance includes steps 210 to 260, as follows:

Step 210, acquiring a plurality of raw vehicle data of a target vehicle type in a preset time period, wherein the raw vehicle data comprising vehicle parameters of various data types of the target vehicle type.

Specifically, the raw vehicle data refers to the raw data collected from the target vehicle type without processing, which comprises vehicle parameters of a plurality of data types, such as battery temperature, battery power, vehicle current and other parameters. The target vehicle type includes many target vehicles belonging to the same type with the same battery pack type. The preset time period is a time interval of a set length. In the preset time period, the data of the target vehicle type is collected many times, so as to obtain the plurality of raw vehicle data of target vehicle type in the preset time period. Generally, the preset time period usually takes the historical time period which is a certain length of time away from the current time, that is, the plurality of raw vehicle data obtained are the data of the target vehicle type in a certain length of historical time period. For example, if the preset time period is one year, the raw vehicle data is the data collected within a one year time period.

In one embodiment of the disclosure, a target vehicle has a battery pack. The battery pack comprises a plurality of cells. The raw vehicle data includes the data obtained from the data collection of the battery pack. When the data is collected from the battery pack, the data is collected from each cell of the battery pack, such as collecting the voltage data of each cell.

In the preset time period, the collection of the raw vehicle data is periodic, that is, the data is collected according to the predetermined sampling cycle to obtain the plurality of raw vehicle data, then the raw vehicle data also includes the data obtained from each cell of the battery pack according to the predetermined sampling cycle. For example, the sampling period could be one minute or one second.

In one embodiment of the disclosure, the vehicle parameters include battery power data, battery temperature data, vehicle current data, and battery cell voltage data. Battery power data refers to the remaining power of a battery pack, which is usually expressed as SOC (state of charge). For example, SOC=90%, which means 90% of the remaining power of the battery pack. Battery temperature data refers to the temperature of the battery pack, such as 25° C. The vehicle current data is the current of the battery pack, such as 50 A. Battery cell voltage data refers to the voltage data of all the cells in the battery pack, such as 3V. For each raw vehicle data record, the above vehicle parameters are included.

In one embodiment of the disclosure, in order to more accurately reflect the operation status of the target vehicle, the raw vehicle data can also include data acquisition time, vehicle operation state and other parameters. The vehicle operation state includes a charging state, a driving state, and other states. The charging state is the state of charging the battery pack, and the driving state is mainly the discharge state of the battery pack. For example, one raw vehicle data can include acquisition time, vehicle operation state, battery power data, battery temperature data, vehicle current data, battery cell voltage data, vehicle voltage data, and the like. For example, one raw vehicle data record could include the following: 20210401 10:00:00, charging, 20%, 25° C., −50 A, 3V|3.001V| . . . |2.998V, 300V.

Step 220, grouping the plurality of raw vehicle data into a predefined number of bins based on the data type and the value range of raw vehicle data.

Specifically, after obtaining the raw vehicle data, the plurality of raw vehicle data are divided based on the data types and value ranges of vehicle parameters in the raw vehicle data, and the plurality of raw vehicle data are grouped into multiple bins. The number of bins is fixed and can be preset by the user according to the distribution of multiple raw vehicle data.

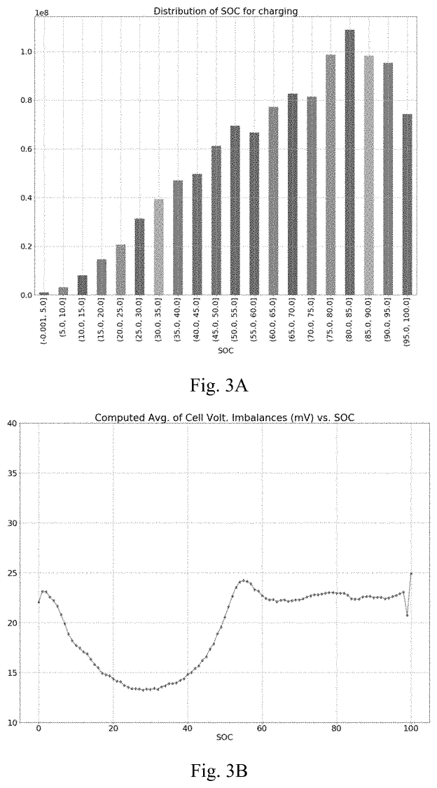

For example, FIG. 3A is a SOC data distribution diagram of a vehicle type in the charging state in one embodiment of the disclosure. The horizontal axis is SOC (unit is %), and the vertical axis is the amount of data. As can be seen from FIG. 3A, the distribution of raw vehicle data is hugely uneven, for example, SOC data more than 50% accounted for a large part of data. If the raw vehicle data is directly used for cell imbalance detection, the uneven distribution of the data will make it easier to detect the condition which accounts for a large proportion, while it is not easy to detect the condition which accounts for a small proportion. As shown in FIG. 3A, SOC data more than 50% is easy to detect, while SOC data less than 50% is not easy to detect, which greatly reduces the detection accuracy.

In order to eliminate the influence of uneven distribution of data on the detection accuracy, firstly, the data is divided into multiple bins according to the raw data values distribution. Finally, the number of bins is set according to the value range of the raw vehicle data. For example, the raw vehicle data may include the battery power data, battery temperature data and vehicle current data. The value range of the battery power data is usually between 0-100%. For example, if a bin is set according to every 10%, 10 bins can be obtained. Supposing that the number of bins corresponding to the battery power data is L, similarly, the number of bins corresponding to the battery temperature data is M, and the number of bins corresponding to the vehicle current data is N, then the total number of bins is the Cartesian product of the numbers of bins corresponding to the above three vehicle parameters, that is, the total number of bins is L*M*N.

In one embodiment of the disclosure, in order to distinguish each bin, each bin can be numbered. For example, the number of the bin is 1, 2, 3, 4, . . . , L*M*N. In order to more intuitively and quickly determine the attributes of the bin (the data type and value range corresponding to the bin), the multi-dimensional number can be directly used. For example, the bins are classified according to the three parameters in the above examples and the multi-dimensional number Aᵢⱼₖ can be configured to represent a specific bin. For example, the battery power data is usually between 0% and 100%. A bin is set for every 10% difference. If the bin number of battery power data is recorded as i, then the value of i is 1, 2, 3 . . . L. In this case, L=10. The bin with 0-10% is set as the number 1 of the data type, the bin with 10%-20% is set as the number 2 of the data type, and so on, and the bin with 90-100% is set as the number 10 of the data type. Similarly, the value range of battery temperature data is usually between (−20° C.) and 50° C. A bin can be set for every 10° C. difference. If the bin number corresponding to battery temperature data is j, then the value of j is 1, 2, 3 . . . M. In this case, M=7, where the bin number of (−20° C.) to (−10° C.) is 1. The value range of vehicle current data is usually between (−200 A) to 0 during charging. A bin could be set for every 25 A difference. If the bin number corresponding to vehicle current data is k, then the value of k is 1, 2, 3 . . . N. In this case, N=8, where the bin number of (−25 A) to 0 is 1. For example, the bin A_{1,1,1} is configured to store the raw vehicle data of the battery power data of 0-10%, the battery temperature data of (−20° C.) to (−10° C.) and the vehicle current data of (−25 A) to 0. Note that the bin size for each dimension may be defined to be the same or different.

In one embodiment of the disclosure, the bin can have two kinds of numbers, one is the number named in Arabic numerals sequence (referred to as numeral number for short) and the other is the multi-dimensional number. The two kinds of numbers correspond to each other one by one. The numeral number can facilitate the subsequent calculation of the bin, and the multi-dimensional number can facilitate the grouping of the raw vehicle data. For example, the numeral number of bin A_{1,1,1} is 1, the numeral number of bin A_{1,1,2} is 2, the numeral number of bin A_{1,1,8} is 8, the numeral number of bin A_{1,2,1} is 9, the numeral number of bin A_{1,3,1} is 10, and so on.

In one embodiment of the present disclosure, when putting the raw vehicle data into the bin, firstly, the dimension number of the target bin corresponding to the raw vehicle data is determined according to the data type of the vehicle parameters in the raw vehicle data. Then, the specific number corresponding to the dimension number is determined according to the specific value range of the vehicle parameters in the raw vehicle data. Finally, the target bin is determined according to the number of all dimension numbers, and the raw vehicle data is put in the corresponding target bin. For example, if the bin adopts a three-dimensional number, the grouping of the raw vehicle data includes: determining the first number of the bin according to the value of the battery power data in the raw vehicle data; determining the second number of the bin according to the value of the battery temperature data in the raw vehicle data; and determining the third number of the bin according to the value of the vehicle current data in the raw vehicle data. The target bin is determined according to the first number, the second number and the third number of the bin, and the raw vehicle data is put in the target bin. For example, if the data type is battery power data, the number dimension is the first; if the data type is battery temperature data, the number dimension is the second; and if the data type is vehicle current data, the number dimension is the third. If the battery power data is 5%, the first number of the bin is 1; if the battery temperature data is 5° C., the second number of the bin is 3; and if the vehicle current data is (−20 A), the third number of the bin is 1. Finally, the target bin number is A_{1,3,1}, and the raw vehicle data can be put in the target bin A_{1,3,1}.

In the technical solution of the disclosure, the data in each bin belongs to the same range through grouping of the plurality of raw vehicle data, that is, the data distribution in each bin is more uniform, and the subsequent calculation will be carried out on the basis of each bin, so the influence of uneven data distribution of raw vehicle data is greatly reduced with this data down-sampling technique, and the detection accuracy is improved. In addition, since the number of bins is preset, the number of bins is independent of the number of raw vehicle data in the process of use, so it is easy to expand the data according to the raw vehicle data and improve the data richness.

Step 230, determining an observed bin-level cell voltage imbalance of the bin based on the plurality of raw vehicle data in each bin, wherein the observed bin-level cell voltage imbalance is an average of all observed cell voltage imbalances in the bin, and the observed cell voltage imbalance is a difference between the maximum battery cell voltage and the minimum battery cell voltage in a battery pack of the target vehicle type.

Specifically, for the battery pack in the vehicle, the voltage imbalance is also named as the cell voltage imbalance, which is defined as a difference between the maximum voltage and the minimum voltage of the cells in the battery pack, and the observed cell voltage imbalance is a difference between the maximum voltage and the minimum voltage of the cells in each raw vehicle data record. The raw vehicle data are grouped into bins. The bin-level cell voltage imbalance of each bin is represented by the observed bin-level cell voltage imbalance, which is the average of all the observed cell voltage imbalances in each bin. The observed bin-level cell voltage imbalance can reflect the state of cell voltage imbalance under the vehicle operation conditions represented by the bin (that is, the value range of vehicle parameters of various data types defined by the bin).

In one embodiment of the present disclosure, the observed bin-level cell voltage imbalance specifically includes: determining the maximum battery cell voltage and minimum battery cell voltage of the battery pack according to a plurality of battery cell voltage data in the raw vehicle data, and the battery cell voltage data are obtained by sampling each cell of the battery pack at the same time; determining a difference between the maximum value of the battery cell voltage and the minimum value of the battery cell voltage to obtain the observed cell voltage imbalance; and determining the observed bin-level cell voltage imbalance based on the average of all observed cell voltage imbalances in the bin.

In one embodiment, when calculating the observed cell voltage imbalance, the raw voltage data of multiple cells of the battery pack is collected at the same time. Firstly, the maximum battery cell voltage and minimum battery cell voltage in the multiple battery cells voltage data of one vehicle with the same collection time are determined, and then the observed cell voltage imbalance of the battery pack at the acquisition time is obtained by subtracting the minimum battery cell voltage from the maximum battery cell voltage. Finally, the observed bin-level cell voltage imbalance is obtained by taking the average of all the observed cell voltage imbalances in this bin.

In one embodiment of the present disclosure, a relationship between observed bin-level cell voltage imbalances and SOC in the charging state for one vehicle type is shown in FIG. 3B, the horizontal axis is SOC (unit is %), and the vertical axis is the observed bin-level cell voltage imbalance (that is, the average of cell voltage imbalances, unit is mV). The SOC data corresponds to the data in the charging state as shown in FIG. 3A. As can be seen from FIG. 3B, the relationship between the observed bin-level cell voltage imbalances and SOC can be predicted intuitively, and the observed bin-level cell voltage imbalance can be used as the best unbiased estimation of the true value of cell voltage imbalance of normal battery packs, so that the risk of cell voltage imbalance can be detected by calculating the observed bin-level cell voltage imbalance.

In an embodiment of the present disclosure, FIG. 3C shows a SOC data distribution diagram of a vehicle type in the driving state, and FIG. 3D is a diagram of a relationship between observed bin-level cell voltage imbalances and SOC of the same vehicle type in the driving state. The relationship between SOC and bin-level cell voltage imbalances in the driving state is similar to that in the charging state.

Step 240, building a machine learning model to predict bin-level cell voltage imbalance of the bin, based on the bin parameters defined.

Specifically, for each bin, the bin parameters represent a specific kind of vehicle operation condition. For example, the vehicle operation condition represented by the bin A_{1,1,1} are as follows: the battery power data is 0-10%, the battery temperature data is (−20° C.) to (−10° C.), and the vehicle current data is (−25 A) to 0. The predicted bin-level cell voltage imbalance is an expected value of the cell voltage imbalance corresponding to the vehicle operation condition represented by the bin parameters. Generally, the bin parameters are features for the machine learning model.

In one embodiment of the present disclosure, the method of predicting bin-level cell voltage imbalance specifically includes: preprocessing the bin parameters of each bin to determine the vehicle condition parameters corresponding to the bin, and the vehicle condition parameters are one or more vehicle parameters representing the operation status of the target vehicle; training a Random Forest model to map the vehicle condition parameters to the observed bin-level cell voltage imbalance, that is, the RF model is configured to predict the bin-level cell voltage imbalance based on the vehicle condition parameters; and applying the trained RF model to obtain the predicted bin-level cell voltage imbalance of the bin based on the vehicle condition parameters. As mentioned above, each bin represents a vehicle operating condition, and each vehicle operating condition corresponds to a set of vehicle condition parameters. Generally, the data type contained in the vehicle condition parameters is the data type contained in the bin parameters, and the parameter value of each data type can be set to the mean value of the corresponding data type range of the bin parameters. For example, the bin A_{1,1,1} represents: the battery power data of 0-10%, the battery temperature data of (−20° C.) to (−10° C.) and the vehicle current data of (−25 A) to 0. The corresponding vehicle condition parameters are: battery power data is 5%, battery temperature data is (−15° C.), and vehicle current data is (−12.5 A). After getting the vehicle condition parameters, the Random Forest (RF) model can be trained to map the vehicle condition parameters to the observed bin-level cell voltage imbalance, that is, the RF model is configured to predict the bin-level cell voltage imbalance based on the vehicle condition parameters. RF models can minimize parameter tuning, which is convenient and fast to use. Of course, technicians can also choose other machine learning models according to the actual needs, as long as they can realize the prediction of bin-level cell voltage imbalance.

In one embodiment of the disclosure, before applying the trained random forest model, the method also includes the training process of the RF model, specifically including: acquiring a plurality of sample vehicle data of the target vehicle type as a sample dataset, wherein the sample vehicle data comprises the vehicle parameters of various data types of the target vehicle type; randomly selecting a part of the sample data set as a training dataset; and training the Random Forest model through the training dataset until the model parameter R2 reaches a preset threshold, to obtain a trained random forest model. Note that each different vehicle/battery type would need its own specific random forest model trained separately.

Specifically, multiple sample vehicle data under various operating conditions are obtained as the sample dataset, and the data type of vehicle parameters in the sample vehicle data is the same as that in the raw vehicle data, and the multiple sample vehicle data are also grouped into bins, referring to the previous description of the raw vehicle data, which will not be repeated here. Then a part of the sample dataset is randomly selected as the training data set, and the rest can be used as the test dataset to train the RF model. In the process of model training, weight is given to each bin to compensate for the phenomenon that the number of observed cell voltage imbalance records in some bins is lower than that in other bins. The weight of each bin is the reciprocal of the standard deviation of the observed cell voltage imbalance represented by all sample vehicle data in the bin. When the model parameter R2 reaches the preset threshold in the training process, it is considered that the RF model training is completed and the trained RF model is obtained. When the model parameter R2 reaches 99%, it is considered that the model training is good. After finishing training, the RF model can be tested by the test dataset (at this time, the training dataset is not configured to test to avoid overfitting the model) to verify the accuracy of the model.

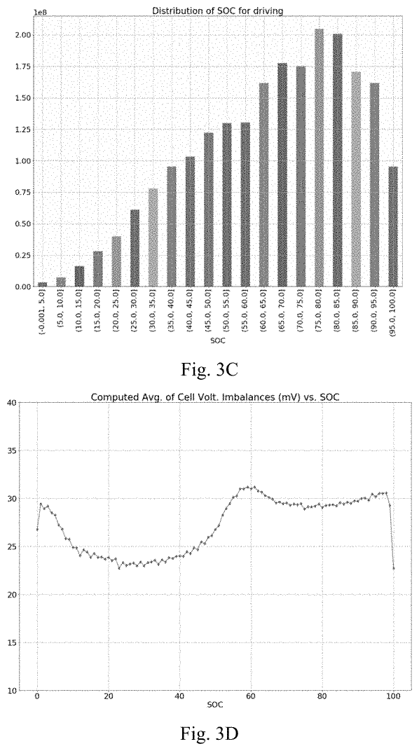

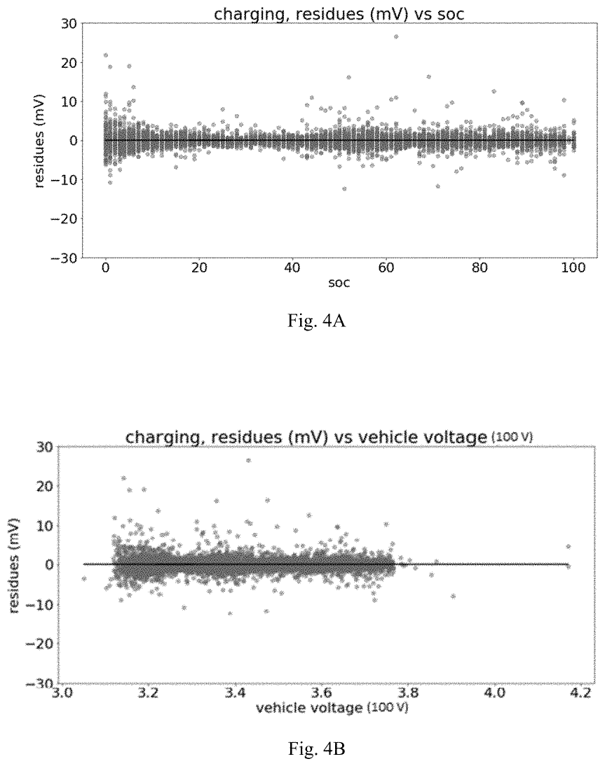

In one embodiment of the present disclosure, the difference between the predicted value of the model and the actual observed value is called model residue. The RF model is tested and verified with the training dataset in the charging state. There is no observed systematic bias in the residues (i.e., differences between observed and predicted) vs. the input features of the model (the input features are the vehicle condition parameters in the raw vehicle data). As shown in FIGS. 4A-4D, the relationship between machine learning model residues (mV) and SOC for charging state, the relationship between machine learning model residues (mV) and vehicle voltage (100 V) for charging state, the relationship between machine learning model residues (mV) and vehicle current (A) for charging state, and the relationship between machine learning model residues (mV) and battery average temperature (° C.) for charging state are shown respectively. FIG. 5 also shows the distribution of machine learning model residues (mV) in the charging state. It can be seen from FIG. 5 that the residual distribution is very similar to the normal distribution.

Step 250, determining a difference between the observed bin-level cell voltage imbalance and the predicted bin-level cell voltage imbalance of each bin, to obtain an unaccounted bin-level cell voltage imbalance.

Specifically, the unaccounted bin-level cell voltage imbalance is obtained by subtracting the predicted bin-level cell voltage imbalance of each bin from the observed bin-level cell voltage imbalance. The unaccounted bin-level cell voltage imbalance represents the difference between the observed cell voltage imbalance and the expected cell voltage imbalance of the target vehicle.

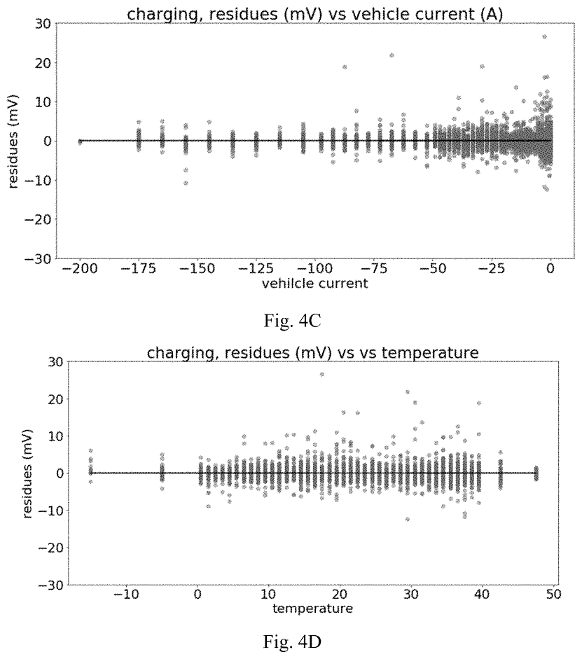

In one embodiment of the disclosure, the RF model can capture the relationship between the observed bin-level cell voltage imbalance and the vehicle operation condition (a bin represents a vehicle operation condition) well, so that the unaccounted bin-level cell voltage imbalance is close to zero for a normal or low risk vehicle. As shown in FIGS. 6A-6C, FIG. 6A shows a relationship between the observed bin-level cell voltage imbalances (mV), the unaccounted bin-level cell voltage imbalances (mV) and SOC for a normal vehicle example, where curve 1 obs. imbalance: charging) shows the relationship between the observed bin-level cell voltage imbalances and SOC in the charging state. Curve 2 (obs. imbalance: driving) shows the relationship between the observed bin-level cell voltage imbalances and SOC in the driving state, and curve 3 (unacc.imbalance: charging) shows the relationship between the unaccounted bin-level cell voltage imbalances and SOC in the driving state, and curve 4 (unacc. Imbalance: charging) shows the relationship between the unaccounted bin-level cell voltage imbalances and SOC in the charging state. FIG. 6B shows the relationship between the observed bin-level cell voltage imbalances (mV), the unaccounted bin-level cell voltage imbalances (mV) and vehicle current (A) for the same vehicle example, where curve 1 (obs. imbalance: charging) shows the relationship between the observed bin-level cell voltage imbalances and the vehicle current in the charging state, curve 2 (obs. imbalance: driving) shows the relationship between the observed bin-level cell voltage imbalances and the vehicle current in the driving state, curve 3 (unacc. imbalance: driving) shows the relationship between the unaccounted bin-level cell voltage imbalances and vehicle current in the driving state, curve 4 (unacc. imbalance: charging) shows the relationship between the unaccounted bin-level cell voltage imbalances and vehicle current in the charging state. FIG. 6C shows the relationship between the observed bin-level cell voltage imbalances (mV), the unaccounted bin-level cell voltage imbalances (mV) and the average battery pack temperature (that is, the avg. temperature, the unit is ° C.) for the same vehicle example, where the curve 1 (obs. imbalance: charging) shows the relationship between the observed bin-level cell voltage imbalances and the average battery pack temperature in the charging state, the curve 2 (obs. imbalance: driving) shows the relationship between the observed bin-level cell voltage imbalances and the average battery pack temperature in the driving state, the curve 3 (unacc. imbalance: driving) shows the relationship between the unaccounted bin-level cell voltage imbalances and average battery pack temperature in the driving state, curve 4 (unacc. Imbalance: charging) shows the relationship between the unaccounted bin-level cell voltage imbalances and average battery pack temperature in the charging state.

Step 260, determining whether there is a high risk of cell imbalance in a target vehicle based on a weighted average of the plurality of unaccounted bin-level cell voltage imbalances.

Specifically, perform weighted average processing on all unaccounted bin-level cell voltage imbalances for each vehicle, and determine whether the target vehicle has a cell imbalance risk based on the weighted averages. The calculation method of the combined weighted average is as follows:

$$combined weighted average = \frac{{\sum }_{i} \sqrt{{ω}_{i} {γ}_{i}} \cdot {v}_{i}}{{\sum }_{j} \sqrt{{ω}_{j} {γ}_{j}}}$$

where vᵢ is the unaccounted bin-level cell voltage imbalance in bin i, ωᵢ is the decay weight, ωᵢ=baseⁿ, base is a positive number smaller than 1, n represents the number of days to the current date from the acquisition date of data in the i-th bin, hence the further to the past a bin is, the smaller its decay weight, γᵢ is the density weight, γᵢ=\sqrt{Sᵢ}, Sᵢ represents the data amount of the i-th bin, a bin with higher number of raw records has higher density weight, and the range of i and j is 0˜L*M*N.

In one implementation of the present disclosure, when the weighted average is greater than a predefined voltage threshold, it is determined that the target vehicle has a high cell imbalance risk. If the weighted average of the multiple unaccounted bin-level cell voltage imbalances is less than or equal to the predefined voltage threshold, it is determined that there is no or low cell imbalance risk in the target vehicle.

In one implementation of the disclosure, in order to further improve the accurate detection of whether the target vehicle has a high cell imbalance risk, more vehicle parameters can be obtained for condition judgment. For example, obtaining the total driven distance of the target vehicle in a preset time period, on the premise that the weighted average is greater than the predefined voltage threshold, if the total driven distance is greater than a predefined distance threshold, it is considered that the target vehicle has the high risk of cell imbalance. For another example, obtaining the end odometer on the last day of the target vehicle, on the premise that the weighted average is greater than the predefined voltage threshold and the total driven distance is larger than the predefined distance threshold, if the total end odometer is greater than a predefined odometer threshold, it is considered that the target vehicle has a high risk of cell imbalance.

In one embodiment of the present disclosure, if it is determined that there is a high risk of cell imbalance in the target vehicle, the target user associated with the target vehicle is identified, and the cell imbalance alarm information is sent to the target user, so that the target user can know the battery condition of the target vehicle in time, maintain the battery in time to avoid unexpected breakdowns or accidents.

In the technical solution in the embodiments of the disclosure, the raw vehicle data obtained includes vehicle parameters of various data types, so that vehicle battery cell imbalance detection has taken into account vehicle parameters of more data types, that is, to detect vehicle battery cell imbalance under different vehicle operation conditions, so as to improve detection accuracy and reliability. Through the data down-sampling technique, the influence of uneven distribution of multiple raw vehicle data is reduced, and the accuracy of vehicle battery cell imbalance detection is improved. Finally, the unaccounted bin-level cell voltage imbalance is calculated to judge whether there is cell imbalance risk in the target vehicle, and the cell imbalance risk is quantified to further improve the accuracy of vehicle battery cell imbalance detection.

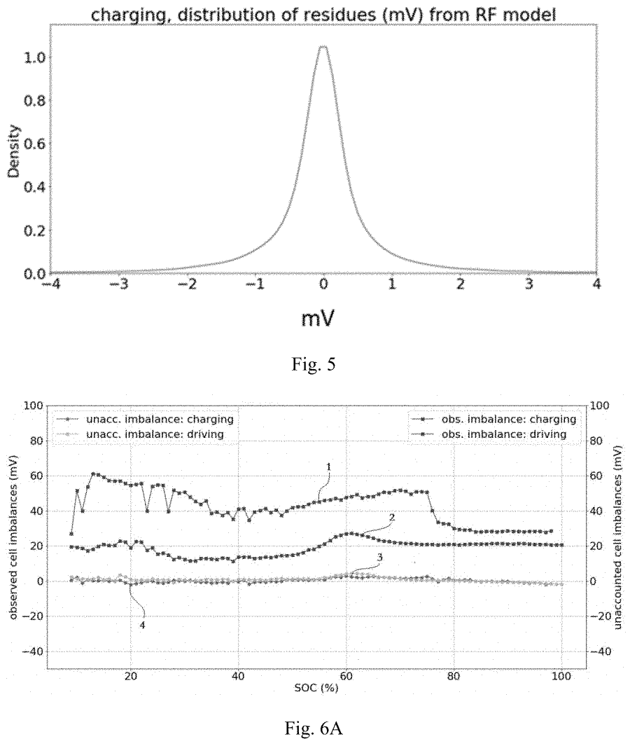

FIG. 7 is a flow diagram of constructing an unaccounted cell voltage imbalances variation curve in an embodiment of the present disclosure. The technical solution shown in FIG. 7 is a further extension of the technical solution provided by the previous embodiment. The unaccounted cell voltage imbalance variation curve is constructed before determining whether the target vehicle has the cell imbalance risk based on the weighted average of the multiple unaccounted bin-level cell voltage imbalances, that is, before step 260 of the above embodiment. As shown in FIG. 7, a method of constructing an unaccounted cell voltage imbalance curve provided by an embodiment of the present disclosure includes steps 410 to 460, which are specifically as follows:

Step 410, determining number of available bins in the preset time period, wherein the available bins refer to the different vehicle operation conditions obtained from the raw vehicle data.

Step 420, determining current observed bin-level cell voltage imbalances of the available bins based on a plurality of battery cell voltage data in the bins.

Specifically, the current observed bin-level cell voltage imbalances are obtained by calculating the battery cell voltage imbalances in the available bins and the calculation method is the same as that in the previous step 230. Please refer to the relevant description in step 230, which will not be repeated here.

Step 430, applying the trained RF model on the bin parameters of each available bin to obtain predicted bin-level cell voltage imbalances.

Specifically, the predicted bin-level cell voltage imbalance refers to the expected bin-level cell voltage imbalance of the bin representing the vehicle operation condition, and the calculation method is the same as that in the previous step 240. Please refer to the relevant description in step 240, which will not be repeated here.

Step 440, determining differences between the current observed bin-level cell voltage imbalances and the predicted bin-level cell voltage imbalances of each bin, and obtaining a plurality of current unaccounted bin-level cell voltage imbalances of all available bins.

Specifically, subtracting the predicted bin-level cell voltage imbalances from the current observed bin-level cell voltage imbalances of each available bin to obtain the current unaccounted bin-level cell voltage imbalances of the available bins.

Step 450, determining a daily weighted average for each day in the preset time period based on a weighted average of the current unaccounted bin-level cell voltage imbalances of available bins.

Specifically, the daily weighted average is the weighted average of the current unaccounted bin-level cell voltage imbalances of the available bins on that day. The daily weighted average of day D is calculated as follows:

$$daily weighted {average}_{d} = \frac{{\sum }_{k} {γ}_{k} \cdot {v}_{k}}{{\sum }_{k} {γ}_{k}}$$

The value of k ranges from 1 to m, and m represents the number of available bins as of day D.

Step 460, constructing an unaccounted cell voltage imbalance change trend curve based on daily weighted averages of each day in the preset time period, wherein the unaccounted cell voltage imbalance change trend curve represents a change relationship of the daily weighted average with the date.

Specifically, the daily weighted averages are fitted to construct the unaccounted cell voltage imbalance change trend curve, which reflects the relationship between the daily weighted average and time (date).

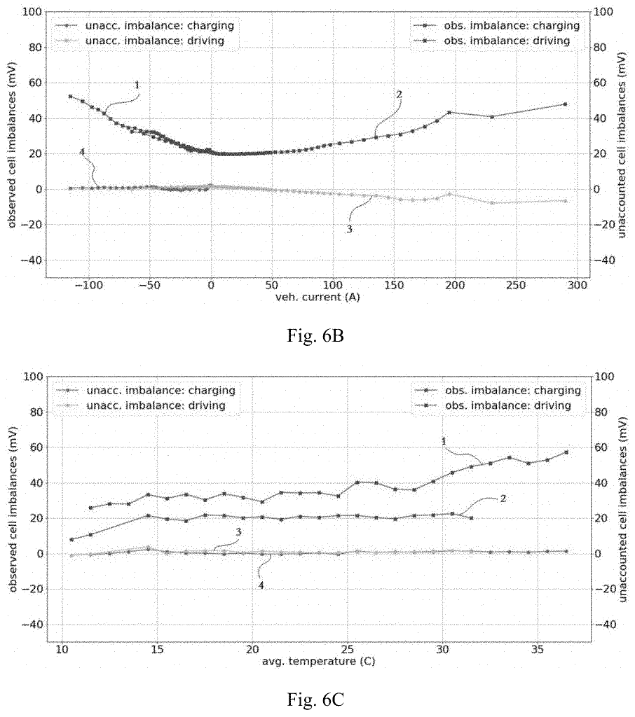

In one embodiment of the present disclosure, as shown in FIG. 8, a change relationship between the daily weighted average of the unaccounted cell voltage imbalance and time (daily average of differences between observed and predicted cell balances (mV)) of one normal vehicle example is shown. In FIG. 8, the horizontal axis is the day, and the vertical axis is the daily weighted average (i.e. weighted avg. of unaccounted cell voltage imbalances (mV)). As can be seen from FIG. 8, the daily weighted average fluctuates in a small range with time, and the fluctuation range is not large. This is an example of the change of the daily weighted averages of normal vehicles (i.e. vehicles with no or low risk of cell imbalance).

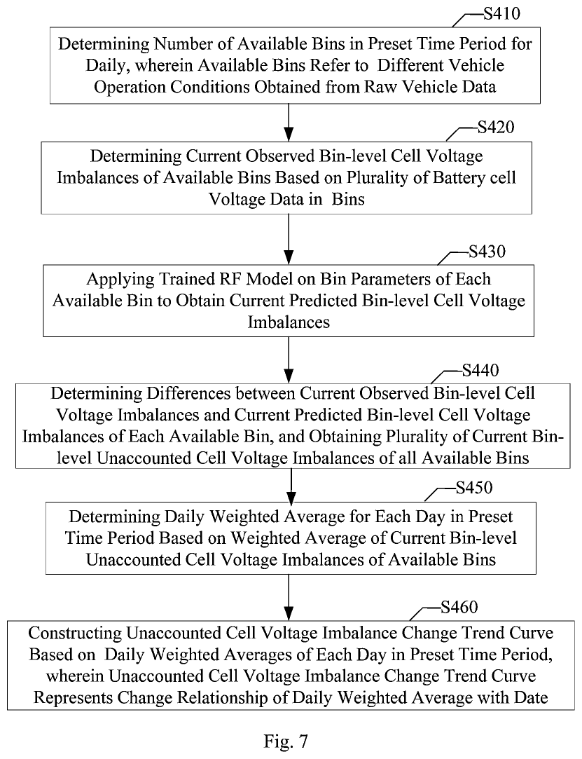

In an embodiment of the present disclosure, FIG. 9A shows a relationship between the observed bin-level cell voltage imbalances (i.e. observed cell voltage imbalances, in mV), the unaccounted bin-level cell voltage imbalances (i.e. unaccounted cell voltage imbalances, in mV) and SOC of an example of a high-risk vehicle (i.e. vehicles with high risk of cell imbalance). FIG. 9B shows the change relationship between daily weighted average and time of the same high risk vehicle example (i.e. daily average of differences between observed and predicted cell voltage imbalances (mV)). In FIG. 9A, curve 1 (obs. imbalance: charging) shows the relationship between the observed bin-level cell voltage imbalances and SOC in the charging state, curve 2 (obs. imbalance: driving) shows the relationship between the observed bin-level cell voltage imbalances and SOC in the driving state, curve 3 (unacc. imbalance: driving) shows the relationship between the unaccounted bin-level cell voltage imbalances and SOC in the driving state, curve 4 (unacc. imbalance: charging) shows the relationship between the unaccounted bin-level cell voltage imbalances and SOC in the charging state. In FIG. 9B, the horizontal axis is the date (day), and the vertical axis is the daily weighted average (weighted average of unaccounted cell voltage imbalances (mV)). As can be seen from FIG. 9B, the daily weighted average of high-risk vehicles fluctuates greatly, and the unaccounted cell voltage imbalances value is also large, which is easy to detect.

In one embodiment of the present disclosure, constructing the unaccounted cell voltage imbalance change trend curve includes: performing linear regression on all daily weighted averages in the preset time period to obtain the unaccounted cell voltage imbalance change trend curve for each vehicle, as shown in the following formula:

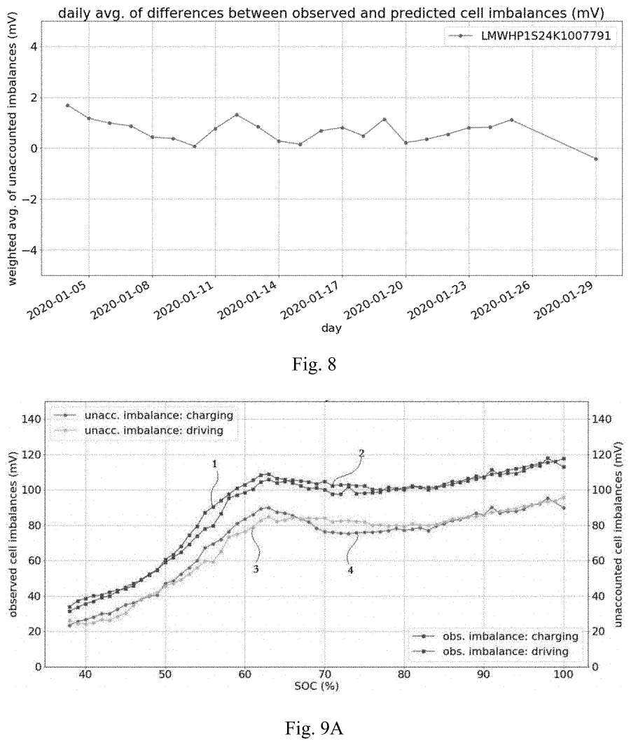

daily weighted average_{d}=β₀+β₁·t+β₂·s

Where t is calculated as K subtracting the number of days from the monitoring day—so that t equals K for the monitoring day (last day). β₀,β₁ and β₂ are the coefficients of the linear regression equation, and s is the daily weighted average of SOC. The primary reason for adding SOC dimension is to reduce variation in time series of unaccounted bin-level cell imbalances attributed to SOC variation. It was found empirically that for high-risk vehicles, the correlation between daily weighted unaccounted bin-level cell imbalances and daily weighted SOC is significant. Consequently, adding the SOC dimension improves the accuracy of the estimations of the offset (β₀) and the trend (β₁) coefficients. For example, referring to FIG. 10, curve 1 is the daily weighted average of observed cell voltage imbalance change curve (without eliminating the influence of SOC data), curve 2 is the unaccounted cell voltage imbalance change curve after the influence of SOC is eliminated with the linear regression model, and curve 3 is the best estimate of the unaccounted cell voltage imbalance change trend curve. It can be seen from FIG. 10 that the construction accuracy of the unaccounted cell voltage imbalance change trend curve can be improved by adding SOC dimension into linear regression.

In one embodiment of the present disclosure, after constructing the unaccounted cell voltage imbalance change trend curve, the step of determining whether there is high cell imbalance risk in a target vehicle based on the unaccounted bin-level cell voltage imbalances (i.e. step 260 in the above embodiment) specifically includes: determining an unaccounted cell voltage imbalance variation trend based on the slope calculated from the linear regression of the unaccounted cell voltage imbalance change trend curve; determining that there is a high risk of cell imbalance in the target vehicle, if the weighted average of the unaccounted bin-level cell voltage imbalances is greater than a preset voltage threshold, and the unaccounted cell voltage imbalance variation trend is greater than a preset trend threshold; or determining that there is no or low risk of cell imbalance in the target vehicle, if the weighted average of the unaccounted bin-level cell voltage imbalances is less than the preset voltage threshold, or if the unaccounted cell voltage imbalance variation trend is less than or equal to the preset trend threshold.

Specifically, the unaccounted cell voltage imbalance variation trend mainly reflects the change trend of the daily weighted average of the current unaccounted bin-level cell voltage imbalances, such as increasing or decreasing, while the daily weighted average is calculated from the current unaccounted bin-level cell voltage imbalances. The unaccounted cell voltage imbalance variation trend is a slope calculated from the linear regression of the unaccounted cell voltage imbalance change trend curve. Under the condition that the weighted average of the unaccounted bin-level cell voltage imbalances is greater than the preset voltage threshold, if the unaccounted cell voltage imbalance variation trend is greater than the preset trend threshold, the target vehicle is considered to have high risk of cell imbalance.

In one embodiment of the disclosure, the unaccounted cell voltage imbalance variation trend is greater than the preset trend threshold, that is, the slope of the unaccounted cell voltage imbalance change trend curve is greater than the preset trend threshold (for example, the preset trend threshold is −0.01).

In one implementation of the disclosure, in order to further improve the accurate detection of whether the target vehicle has a high cell imbalance risk, more vehicle parameters can be obtained for condition judgment. Further, obtaining the total driven distance of the target vehicle in a preset time period and the end odometer on the last day of the target vehicle, if the weighted average of unaccounted bin-level cell voltage imbalances is greater than the predefined voltage threshold, the total driven distance is larger than the predefined distance threshold, the total end odometer is greater than the predefined odometer threshold, and the unaccounted cell voltage imbalance variation trend is greater than the predefined trend threshold, it is considered that the target vehicle has high risk of cell imbalance.

In one embodiment of the disclosure, the unaccounted cell voltage imbalance change trend curve can also be displayed through a visualization interface. When it is determined that there is high risk of cell imbalance in the target vehicle, a list of causes or symptoms leading to cell imbalance is displayed through the visual interface, such as high SOC, which can help quickly and easily investigate the causes of cell imbalance.

In the technical solution provided by the embodiments of the disclosure, the accuracy and reliability of vehicle battery cell imbalance risk detection are further improved by calculating the unaccounted cell voltage imbalance variation trend of the target vehicle, so as to avoid misjudgment of vehicles without cell imbalance risk.

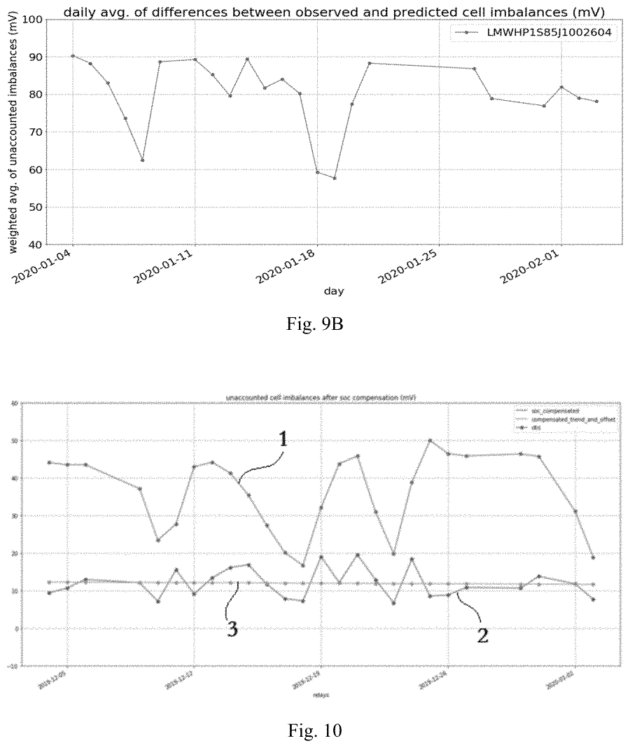

FIG. 11 is a flow diagram of further steps of determining whether there is high risk of cell imbalance in a target vehicle based on a weighted average of the plurality of unaccounted bin-level cell voltage imbalances in an embodiment of the disclosure. This embodiment is a further expansion of step 260 of the above embodiment. As shown in FIG. 11, step 260 further includes step 610 to step 630, which are specifically as follows:

Step 610, determining a trend score and a weighted average score of the unaccounted bin-level cell voltage imbalances for each vehicle.

Specifically, when it is detected that there is a high risk of cell imbalance in the target vehicle, such a vehicle can be called a high risk vehicle. In some cases, there may be multiple high risk vehicles. For example, for all vehicles in a fleet (for example there may be 2000 vehicles), multiple high risk vehicles may be detected. The trend score (score_{trend}) of each vehicle in the fleet is calculated as follows:

$${score}_{trend} = \frac{{trend}_{i} - min ( trend )}{max ( trend ) - min ( trend )}$$

trendᵢ refers to the unaccounted cell voltage imbalance variation trend of the l-th vehicle; max_{(trend)} is the maximum value of the unaccounted cell voltage imbalance variation trend of all vehicles in the fleet; min(trend) is the minimum value of the unaccounted cell voltage imbalance variation trend of all vehicles in the fleet.

The calculation method of the weighted average score (score_{imbalances}) of the multiple unaccounted bin-level cell voltage imbalances of each vehicle in the fleet is similar to the calculation method of the trend score, as shown below:

$${score}_{imbalance} = \frac{{imbalance}_{l} - min ( imbalance )}{max ( imbalance ) - min ( imbalance )}$$

imbalanceₗ refers to the weighted average of the multiple unaccounted bin-level cell voltage imbalances of the l-th vehicle (hereinafter referred to as the weighted average); max(imbalance) is the maximum value of the weighted averages of all vehicles in the fleet; min(imbalance) is the minimum value of the weighted averages of all vehicles in the fleet.

In one embodiment of the disclosure, before calculating the risk score, the method also includes: normalizing the risk score of the unaccounted cell voltage imbalance variation trend and weighted average of vehicles. Through normalization, the trend score and the weighted average score can be between 0 and 1, which is convenient for comparison.

Step 620, determining a vehicle risk score in terms of cell imbalance of all the vehicles in the fleet based on the trend score and the weighted average score, wherein the vehicle risk score is configured to represent the risk degree of cell imbalance of all the vehicles in the fleet.

Specifically, the vehicle risk score is a quantification of the risk degree of all vehicles, which reflects the risk degree of cell imbalance of all vehicles.

$$score = {\sum }_{k ∈ ( imbalance , trend )} {w}_{k} ⋆ {score}_{k}$$

where vₖ^{s} are the score weights.

Step 630, ranking all the vehicles based on the risk scores of all the vehicles, so as to identify the high risk vehicles based on the risk degrees of cell imbalance.

Specifically, all the vehicles are ranked based on the calculated vehicle risk scores. The closer the vehicle risk score is to 1, the higher the ranking is, indicating that the risk of cell imbalance is higher. Technicians can make priority maintenance to high-ranking vehicles according to the risk degree of cell imbalance of each vehicle. The ranking can be displayed through a visualization interface.

In the technical solution in an embodiment of the disclosure, all vehicles are ranked by the vehicle risk scores, which effectively reflect the risk degree of cell imbalance of each vehicle, and helps the technicians to quickly understand the condition of each vehicle, so as to give priority to the maintenance of vehicles with higher risk degree of cell imbalance.

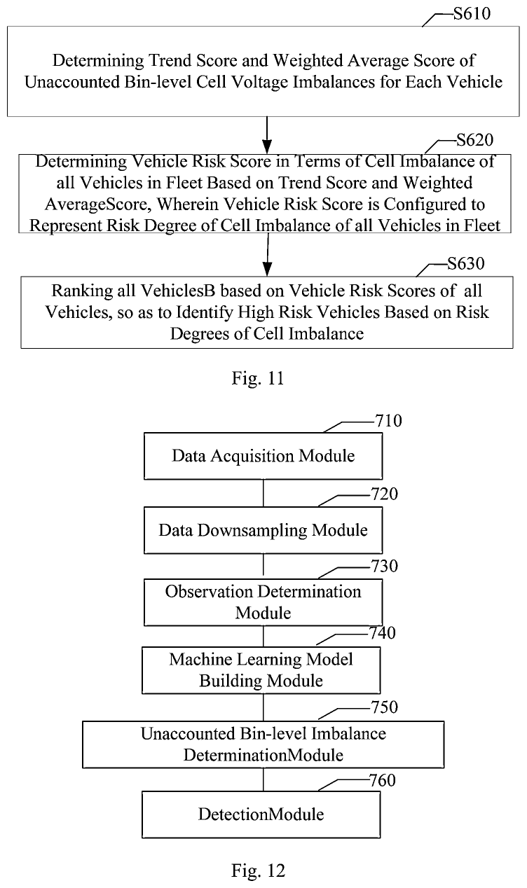

The following describes a system embodiment of the disclosure, which can be configured to implement the method for detecting high risk vehicles with cell imbalance in the above embodiment of the disclosure. FIG. 12 shows a block diagram of a device for detecting high risk vehicles with cell imbalance in one embodiment of the disclosure. As shown in FIG. 12, a device for detecting high risk vehicles with cell imbalance provided by an embodiment of the present disclosure includes:

data acquisition module 710, configured to acquire a plurality of raw vehicle data of a target vehicle type in a preset time period, the raw vehicle data comprising vehicle parameters of various data types of the target vehicle type;
data downsampling module 720, configured to group the plurality of raw vehicle data into a predefined number of bins based on the data type and the value range of raw vehicle data; observation determination module 730, configured to determine an observed bin-level cell voltage imbalance of the bin, wherein the observed bin-level cell voltage imbalance is an average of all observed cell voltage imbalances in the bin, and the observed cell voltage imbalance is a difference between the maximum battery cell voltage and the minimum battery cell voltage in a battery pack of the target vehicle type;
machine learning model building module 740, configured to building a machine learning model to obtain predicted bin-level cell voltage imbalance of each bin, based on the bin parameters defined;
unaccounted bin-level imbalance determination module 750, configured to determine a difference between the observed bin-level cell voltage imbalance and the predicted bin-level cell voltage imbalance of each bin, to obtain an unaccounted bin-level cell voltage imbalance; and
detection module 760, configured to determine whether there is high risk of cell imbalance in a target vehicle based on a weighted average of the plurality of unaccounted bin-level cell voltage imbalances.

In an embodiment of the present disclosure, a battery pack comprises a plurality of cells, and the raw vehicle data comprises data obtained from data acquisition module 710 of each cell and battery pack/vehicle according to a predetermined sampling period in the preset time period.

In one embodiment of the disclosure, the vehicle parameters include battery power data, battery temperature data, and vehicle current data. The data downsampling module 720 is configured to:

determine a first number of the bin according to the value of the battery power data in the raw vehicle data;
determining a second number of the bin according to the value of the battery temperature data in the raw vehicle data;
determine a third number of the bin according to the value of the vehicle current data in the raw vehicle data; and
determine a target bin according to the first number, the second number and the third number of the bin, and put the raw vehicle data into the target bin.

In one embodiment of the disclosure, the vehicle parameters also include battery cell voltage data, and the observation determination module 730 includes:

voltage extremum determination unit, configured to determine the maximum battery cell voltage and the minimum battery cell voltage of the battery pack at each timestamp according to a plurality of battery cell voltage data in the raw vehicle data, wherein the battery cell voltage data are obtained by sampling each cell of the battery pack at the same time;
observed cell voltage imbalance determination unit, configured to determine a difference between the maximum value of the battery cell voltage and the minimum value of the battery cell voltage to obtain the observed cell voltage imbalance for each battery pack at each timestamp; and
observed bin-level cell voltage imbalance determination unit, configured to determine the observed bin-level cell voltage imbalance based on the average of observed cell voltage imbalances in each bin.

In one embodiment of the disclosure, the machine learning model building module 740 includes:

vehicle condition parameter determination unit, configured to preprocess bin parameters of each bin to determine vehicle condition parameters corresponding to the bin, wherein the vehicle condition parameters are one or more vehicle parameters representing the operation status of the target vehicle;
model training unit, configured to train a Random Forest (RF) model to map the vehicle condition parameters to the observed bin-level cell voltage imbalance, that is, the RF model is configured to predict the bin-level cell voltage imbalance based on the vehicle condition parameters; and
model prediction unit, configured to apply the trained Random Forest model to obtain the predicted bin-level cell voltage imbalance of each bin based on the vehicle condition parameters.

In one embodiment of the disclosure, the machine learning model building module 740 further includes:

sample data acquisition module, configured to acquire a plurality of sample vehicle data of the target vehicle type as a sample dataset, wherein the sample vehicle data comprises the vehicle parameters of various data types of the target vehicle type;
training data selection module, configured to randomly select a part of the sample dataset as a training dataset; and
model training module, configured to train the Random Forest model through the training dataset until the model parameter R2 reaches a preset threshold, to obtain a trained random forest model.

In one embodiment of the disclosure, the unaccounted bin-level imbalance determination module 750 includes:

available bin determination module, configured to determine number of available bins in the preset time period for daily, wherein the available bins refers to the different vehicle operation conditions obtained from the raw vehicle data;
current observation determination module, configured to determine observed bin-level cell voltage imbalances of the available bins based on a plurality of battery cell voltage data in the available bins:
prediction determination module, configured to apply the trained RF model on the bin parameters of each available bin to obtain predicted bin-level cell voltage imbalances;
current unaccounted imbalance determination module, configured to determine differences between the current observed bin-level cell voltage imbalances and the predicted bin-level cell voltage imbalances of each available bin, and obtaining a plurality of current unaccounted bin-level cell voltage imbalances of available bins;
daily weighted average determination module, configured to determine a daily weighted average for each day in the preset time period based on a weighted average of the current unaccounted bin-level cell voltage imbalances of available bins; and
change trend construction module, configured to construct an unaccounted cell voltage imbalance change trend curve based on daily weighted averages in the preset time period for each vehicle, wherein the unaccounted cell voltage imbalance change trend curve represents a change relationship of the daily weighted average with the date.

In one embodiment of the disclosure, a calculation method of the daily weighted average includes:

$$daily weighted {average}_{d} = \frac{{\sum }_{k} {γ}_{k} \cdot {v}_{k}}{{\sum }_{k} {γ}_{k}}$$

where daily weighted average_{d} represents a daily weighted average of the d-though day, the value of k ranges from 1 to m, m represents the number of available bins as of the d-th day, vₖ is the observed cell voltage imbalance of the k-th bin, and γₖ is the density weight.

In one embodiment of the disclosure, the change trend construction module is configured to:

perform linear regression on the daily weighted averages in the preset time period for each vehicle to obtain the unaccounted cell voltage imbalance change trend curve.

In one embodiment of the disclosure, a formula for linear regression processing is:

daily weighted average_{d}=β₀+β₁·t+β₂·s

where t is the number of monitoring days, β₀, β₁ and β₂ are the coefficients of the linear regression equation, and s is the daily weighted average of battery power data.

In one embodiment of the disclosure, the detection module 760 includes:

variation trend determination unit, configured to determine the unaccounted cell voltage imbalance variation trend based on the slope calculated from the linear regression of the unaccounted cell voltage imbalance change trend curve:
risk detection unit, configured to determine that there is a high risk of cell imbalance in the target vehicle, if the weighted average of the unaccounted bin-level cell voltage imbalances is greater than a preset voltage threshold, and the unaccounted cell voltage imbalance variation trend is greater than a preset trend threshold, or configured to determine that there is no or low cell imbalance risk in the target vehicle, if the weighted average of the unaccounted bin-level cell voltage imbalances is less than or equal to the preset voltage threshold or if the unaccounted cell voltage imbalance variation trend is less than or equal to the preset trend threshold.

In one embodiment of the disclosure, the detection module 760 further includes: trend score determination unit, configured to determine a trend score and a weighted average score of the unaccounted bin-level cell voltage imbalances for each vehicle;

vehicle risk score determination unit, configured to determine a vehicle risk score of all the vehicles in the fleet based on the trend score and the weighted average score, wherein the vehicle risk score is configured to represent the risk degree of cell imbalance of all the vehicles in the fleet; and
vehicle ranking unit, configured to rank all the vehicles based on the vehicle risk scores of all the vehicles, so as to identify the high risk vehicles based on the risk degrees of cell imbalance.

In one embodiment of the disclosure, the trend score determination unit includes: normalization unit, configured to normalize the unaccounted cell voltage imbalance variation trend and weighted average of all vehicles.

In one embodiment of the disclosure, the device further includes:

alarm module, configured to identify a target user associated with the target high risk vehicle, and sending cell imbalance alarm information to the target user.

In one embodiment of the disclosure, the device further includes:

displaying module, configured to display the unaccounted cell voltage imbalance change trend curve through a visualization interface.

In one embodiment of the disclosure, a calculation method of combined weighted average of unaccounted bin-level cell voltage imbalances is:

$$combined weighted average = \frac{{\sum }_{i} \sqrt{{ω}_{i} {γ}_{i}} \cdot {v}_{i}}{{\sum }_{j} \sqrt{{ω}_{j} {γ}_{j}}}$$

where vᵢ is the observed bin-level cell voltage imbalance of the i-th bin; ωᵢ is the decay weight; γᵢ is the weight density.

In one embodiment of the disclosure, the detection module 760 includes:

second detection unit, configured to determine that the target vehicle has a high cell imbalance risk, if the weighted average of the plurality of unaccounted bin-level cell voltage imbalances is greater than a preset voltage threshold, or configured to determine that there is no or low cell imbalance risk in the target vehicle, if the weighted average of the plurality of unaccounted bin-level cell voltage imbalances is less than or equal to the preset voltage threshold.

It is understood that these modules or units can be implemented by hardware, software, or a combination of the two. When implemented in hardware, these modules or units may be one or more hardware modules, such as one or more specific integrated circuits. When implemented in software, these modules or units may be one or more computer programs executed on one or more processors.

In one embodiment of the disclosure, a system for detecting vehicle battery cell imbalance is provided. The system is deployed in a vehicle or a cloud server to detect vehicle battery cell imbalance. The system comprises a memory and a processor. The memory is configured to store computer-readable instructions. The processor is configured to read the computer-readable instructions stored in the memory to execute steps in the above-mentioned method for detecting vehicle battery cell imbalance. The system for detecting vehicle battery cell imbalance may be an electronic device.

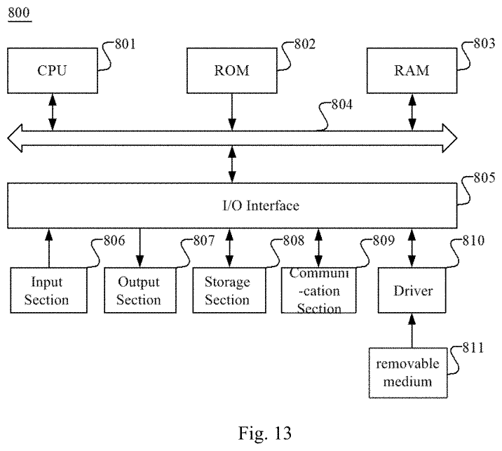

Referring to FIG. 13, a structural diagram of an electronic device 800 in one embodiment of the disclosure is described below. The electronic device 800 shown in FIG. 13 is only an example and shall not bring any limitation on the function and disclosure scope of the embodiments of the present disclosure.

As shown in FIG. 13, the electronic device 800 includes a central processing unit 801 (CPU), which can perform various appropriate actions and processes according to a program stored in the read only memory 802 (ROM) or a program loaded into the random access memory 803 (RAM) from the storage section 808. In the random access memory 803, various programs and data required for system operation are also stored. The CPU 801, the read only memory 802 and the random access memory 803 are connected to each other through the bus 804. The input/output interface 805 (I/O interface) is also connected to the bus 804.

The following components are connected to the input/output interface 805: an input section 806 including a keyboard, a mouse, etc; an output section 807 such as a cathode ray tube (CRT), a liquid crystal display (LCD), and a loudspeaker; a storage section 808 including a hard disk and the like; and a communication section 809 including a network interface card such as a local area network card, a modem, and the like. The communication section 809 performs communication processing via a network such as the Internet. The driver 810 is also connected to the input/output interface 805 as required. A removable medium 811, such as a magnetic disk, an optical disk, a magneto-optical disk, a semiconductor memory, and the like, is mounted on the drive 810 as required, so that a computer program read out from it is mounted into the storage section 808 as required.

In particular, according to the embodiments of the present disclosure, the processes described in the respective method flow charts can be implemented as computer software programs. For example, the embodiment of the present disclosure includes a computer program product, which includes a computer program carried on a computer-readable medium, and the computer program includes program code for executing the method shown in the flow chart. In such an embodiment, the computer program may be downloaded and installed from the network through the communication section 809, and/or installed from the removable medium 811. When the computer program is executed by the central processing unit 801, various functions defined in the system of the present disclosure are executed.

It is easy for those skilled in the art to understand through the above description of the embodiments. The example embodiments described here can be realized by software or by combining software with necessary hardware. Therefore, the technical solution according to the implementation mode of the present disclosure can be embodied in the form of a software product, which can be stored in a non-volatile storage medium (which can be a CD-ROM, U disk, mobile hard disk, etc.) or on a network, including a number of instructions, so that a computing device (which can be a personal computer, a server, a terminal device, or a network device, etc.) to perform the method according to the embodiment of the present disclosure.

In the exemplary embodiment of the present disclosure, there is also a computer storage medium on which computer instructions are stored. When the computer instructions are executed by a processor of the computer, the computer is made to execute the method described in the above method embodiment. The computer storage medium may be a non-transitory computer-readable storage medium, and the computer instructions may be computer-readable instructions.

According to an embodiment of the disclosure, a program product for realizing the method in the embodiment of the above method is also provided, which can adopt a portable compact disk read only memory (CD-ROM) and include program code, and can run on a terminal device, such as a personal computer. However, the program product of the present invention is not limited to this. In this document, the readable storage medium may be any tangible medium containing or storing a program, which may be used by or in combination with an instruction execution system, or device.

Program products can be any combination of one or more readable media. The readable medium may be a readable signal medium or a readable storage medium. The readable storage medium may be, for example, but is not limited to, an electrical, magnetic, optical, electromagnetic, infrared, or semiconductor system, or device, or any combination of the above. More specific examples (non exhaustive list) of readable storage media include: electrical connection with one or more wires, portable disk, hard disk, random access memory (RAM), read only memory (ROM), erasable programmable read only memory (EPROM or flash memory), optical fiber, portable compact disk read only memory (CD-ROM), optical storage device, magnetic storage device Or any suitable combination of the above.

The computer-readable signal medium may include a data signal propagating in baseband or as part of a carrier, in which a readable program code is carried. Such a transmitted data signal may take a variety of forms, including but not limited to electromagnetic signals, optical signals, or any suitable combination of the above. The readable signal medium may also be any readable medium other than a readable storage medium, which may propagate or transmit a program for use by or in combination with an instruction execution system, or device.

The program code contained on the readable medium may be transmitted in any suitable medium, including but not limited to wireless, wired, optical cable, RF, etc., or any suitable combination of the above.

The program code for performing the operation of the invention can be written in any combination of one or more programming languages. The programming languages include object-oriented programming languages such as Java, C++, and conventional procedural programming languages such as “C” or similar programming languages. The program code can be completely executed on the user computing device, partially executed on the user device, executed as an independent software package, partially executed on the user computing device, partially executed on the remote computing device, or completely executed on the remote computing device or server. In cases involving remote computing devices, the remote computing device may be connected to a user computing device through any kind of network, including a local area network (LAN) or a wide area network (WAN), or may be connected to an external computing device (e.g., using an Internet service provider to connect through the Internet).

It should be noted that although several modules or units of the device for action execution are mentioned in the above detailed description, this division is not mandatory. In fact, according to the embodiment of the present disclosure, the features and functions of two or more modules or units described above can be embodied in one module or unit. On the contrary, the features and functions of one module or unit described above can be further divided into multiple modules or units to be embodied.

Furthermore, although the steps of the method in the present disclosure are described in a specific order in the drawings, it is not required or implied that these steps must be performed in the specific order, or that all the steps shown must be performed in order to achieve the desired result. Additional or alternative, some steps may be omitted, multiple steps may be merged into one step execution, and/or a step may be decomposed into multiple step execution, etc.

Those skilled in the art will easily think of other embodiments of the disclosure after considering the description and practicing the invention disclosed herein. The present disclosure is intended to cover any variations, uses or adaptations of the present disclosure. These variations, uses or adaptations follow the general principles of the present disclosure and include common general knowledge or frequently used technical means in the technical field not disclosed by the present disclosure. The description and the embodiments are only regarded as exemplary, and the true scope and spirit of the present disclosure are indicated by the appended claims.

What is claimed is:

1. A method for detecting vehicle battery cell imbalance, comprising:
acquiring a plurality of raw vehicle data of a target vehicle type in a preset time period, the raw vehicle data comprising vehicle parameters of various data types of the target vehicle type;
grouping the plurality of raw vehicle data into a predefined number of bins based on the data type and the value range of raw vehicle data;
determining an observed bin-level cell voltage imbalance of the bin, wherein the observed bin-level cell voltage imbalance is an average of all observed cell voltage imbalances in the bin, and the observed cell voltage imbalance is a difference between the maximum battery cell voltage and the minimum battery cell voltage in a battery pack of the target vehicle type;
building a machine learning model to predict bin-level cell voltage imbalance of each bin, based on bin parameters defined;
determining a difference between the observed bin-level cell voltage imbalance and the predicted bin-level cell voltage imbalance of each bin, to obtain an unaccounted bin-level cell voltage imbalance; and
determining whether there is a high risk of cell imbalance in a target vehicle based on a weighted average of the plurality of unaccounted bin-level cell voltage imbalances.

2. The method of claim 1, wherein the battery pack comprises a plurality of cells, and the raw vehicle data comprises data obtained from data acquisition of each cell, battery pack or vehicle, according to a predetermined sampling period in the preset time period.

3. The method of claim 1, wherein the vehicle parameters comprises battery power data, battery temperature data and vehicle current data, grouping the plurality of raw vehicle data into a predefined number of bins based on the data type and the value range of raw vehicle data, comprising:
determining a first number of the bin according to the value of the battery power data in the raw vehicle data;
determining a second number of the bin according to the value of the battery temperature data in the raw vehicle data;
determining a third number of the bin according to the value of the vehicle current data in the raw vehicle data; and
determining a target bin according to the first number, the second number and the third number of the bin, and putting the raw vehicle data into the target bin.

4. The method of claim 2, wherein the vehicle parameters further comprises battery cell voltage data, determining an observed bin-level cell voltage imbalance of the bin based on the plurality of raw vehicle data in each bin, comprising:
determining the maximum battery cell voltage and the minimum battery cell voltage of the battery pack at each timestamp according to a plurality of battery cell voltage data in the raw vehicle data, wherein the battery cell voltage data are obtained by sampling each cell of the battery pack at the same time;
determining a difference between the maximum value of the battery cell voltage and the minimum value of the battery cell voltage to obtain the observed cell voltage imbalance for each battery pack at each timestamp; and
determining the observed bin-level cell voltage imbalance based on the average of all observed cell voltage imbalances in each bin.

5. The method of claim 1, wherein building a machine learning model to predict bin-level cell voltage imbalance of the bin, based on bin parameters defined, comprises:
preprocessing the bin parameters of each bin to determine vehicle condition parameters corresponding to the bin, wherein the vehicle condition parameters are one or more vehicle parameters representing operation status of the target vehicle;
training a Random Forest model to map the vehicle condition parameters to the observed bin-level cell voltage imbalance, wherein the RF model is configured to predict the bin-level cell voltage imbalance based on the vehicle condition parameters; and
applying the trained RF model to obtain the predicted bin-level cell voltage imbalance of the bin based on the vehicle condition parameters.

6. The method of claim 5, before applying the trained Random Forest model to obtain the predicted bin-level cell voltage imbalance of the bin based on the vehicle condition parameter, the method further comprising:
acquiring a plurality of sample vehicle data of the target vehicle type as a sample dataset, wherein the sample vehicle data comprises the vehicle parameters of various data types of the target vehicle type;
randomly selecting a part of the sample dataset as a training dataset; and
training the Random Forest model through the training dataset until the model parameter R2 reaches a preset threshold, to obtain a trained random forest model.

7. The method of claim 2, before determining whether there is high risk of cell imbalance in a target vehicle based on a weighted average of the plurality of unaccounted bin-level cell voltage imbalances, the method further comprising:
determining number of available bins in the preset time period for daily, wherein the available bins refer to the different vehicle operation conditions obtained from the raw vehicle data;
determining current observed bin-level cell voltage imbalances of the available bins based on a plurality of battery cell voltage data in the bins;
applying the trained RF model on the bin parameters of each available bin to obtain predicted bin-level cell voltage imbalances;
determining differences between the current observed bin-level cell voltage imbalances and the predicted bin-level cell voltage imbalances of each bin, and obtaining a plurality of current unaccounted bin-level cell voltage imbalances of all available bins;
determining a daily weighted average for each day in the preset time period based on a weighted average of the current unaccounted bin-level cell voltage imbalances of available bins; and
constructing an unaccounted cell voltage imbalance change trend curve based on daily weighted averages of each day in the preset time period, wherein the unaccounted cell voltage imbalance change trend curve represents a change relationship of the daily weighted average with the date.

8. The method of claim 7, wherein the calculation method of the daily weighted average is:
$$daily weighted {average}_{d} = \frac{{\sum }_{k} {γ}_{k} \cdot {v}_{k}}{{\sum }_{k} {γ}_{k}}$$
Wherein daily weighted average_{d} represents a daily weighted average of the d-th day, the value of k ranges from 1 to m, m represents the number of available bins as of the d-th day, vₖ is the observed cell voltage imbalance of the k-th bin, and γₖ is the density weight.

9. The method of claim 7, wherein constructing an unaccounted cell voltage imbalance change trend curve based on daily weighted averages in the preset time period, comprises:
performing linear regression on the daily weighted averages in the preset time period to obtain the unaccounted cell voltage imbalance change trend curve for each vehicle.

10. The method of claim 9, wherein a formula for linear regression processing is:
daily weighted average_{d}=β₀+β₁·t+β₂·s
wherein t is the number of monitoring days, β₀, β₁ and β₂ are the coefficients of the linear regression equation, and s is the daily weighted average of battery power data.

11. The method of claim 7, wherein determining whether there is a high risk of cell imbalance in a target vehicle based on a weighted average of the plurality of unaccounted bin-level cell voltage imbalances, comprises:
determining an unaccounted cell voltage imbalance variation trend based on the slope calculated from the linear regression of the unaccounted cell voltage imbalance change trend curve:
determining that there is high risk of cell imbalance in the target vehicle, if the weighted average of the unaccounted bin-level cell voltage imbalances is greater than a preset voltage threshold, and the unaccounted cell voltage imbalance variation trend is greater than a preset trend threshold; or
determining that there is no or low risk of cell imbalance in the target vehicle, if the weighted average of the unaccounted bin-level cell voltage imbalances is less than the preset voltage threshold, or if the unaccounted cell voltage imbalance variation trend is less than or equal to the preset trend threshold.

12. The method of claim 11, wherein determining whether there is a high risk of cell imbalance in a target vehicle based on a weighted average of the plurality of unaccounted bin-level cell voltage imbalances, the method further comprises:
determining a trend score and a weighted average score of the unaccounted bin-level cell voltage imbalances for each vehicle;
determining a vehicle risk score in terms of cell imbalance of all the vehicles in the fleet based on the trend score and the weighted average score, wherein the vehicle risk score is configured to represent the risk degree of cell imbalance of all the vehicles in the fleet; and
ranking all the vehicles based on the vehicle risk scores of all the vehicles, so as to identify the high risk vehicles based on the risk degrees of cell imbalance.

13. The method of claim 12, wherein before determining a trend score and a weighted average score of the unaccounted bin-level cell voltage imbalances for each vehicle, the method further comprises:
normalizing the unaccounted cell voltage imbalance variation trend and weighted average of all vehicles in the fleet.

14. The method of claim 7, wherein after determining whether there is a high risk of cell imbalance in the target vehicle based on a weighted average of the plurality of unaccounted bin-level cell voltage imbalances, the method further comprises:
identifying a target user associated with the target vehicle, and sending cell imbalance alarm information to the target user.

15. The method of claim 7, wherein constructing an unaccounted cell voltage imbalance change trend curve based on daily weighted averages in the preset time period, comprises:
displaying the unaccounted cell voltage imbalance change trend curve through a visualization interface.

16. The method of claim 7, wherein a calculation method of the combined weighted average is:
$$combined weighted average = \frac{{\sum }_{i} \sqrt{{ω}_{i} {γ}_{i}} \cdot {v}_{i}}{{\sum }_{j} \sqrt{{ω}_{j} {γ}_{j}}}$$
wherein vₗ is the observed bin-level cell voltage imbalance of the i-th bin, ωᵢ is the decay weight, and γₗ is the density weight.

17. The method of claim 1, wherein determining whether there is a high risk of cell imbalance in a target vehicle based on weighted average of the plurality of unaccounted bin-level cell voltage imbalances, comprises:
determining that there is high risk of cell imbalance in the target vehicle, if the weighted average of the plurality of unaccounted bin-level cell voltage imbalances is greater than a preset voltage threshold; or
determining that there is low risk of cell imbalance in the target vehicle, if the weighted average of the plurality of unaccounted bin-level cell voltage imbalances is less than or equal to the preset voltage threshold.

18. A system for detecting vehicle battery cell imbalance, deployed in a vehicle or a cloud server, comprising a memory and a processor;
wherein the memory is configured to store computer-readable instructions;
wherein the processor is configured to read the computer-readable instructions stored in the memory to execute steps in a method for detecting vehicle battery cell imbalance;
wherein the method comprises:
acquiring a plurality of raw vehicle data of a target vehicle type in a preset time period, the raw vehicle data comprising vehicle parameters of various data types of the target vehicle type;
grouping the plurality of raw vehicle data into a predefined number of bins based on the data type and the value range of raw vehicle data;
determining an observed bin-level cell voltage imbalance of the bin, wherein the observed bin-level cell voltage imbalance is an average of all observed cell voltage imbalances in the bin, and the observed cell voltage imbalance is a difference between the maximum battery cell voltage and the minimum battery cell voltage in a battery pack of the target type;
building a machine learning model to predict bin-level cell voltage imbalance of each bin, based on bin parameters defined;
determining a difference between the observed bin-level cell voltage imbalance and the predicted bin-level cell voltage imbalance of each bin, to obtain an unaccounted bin-level cell voltage imbalance; and
determining whether there is a high risk of cell imbalance in a target vehicle based on a weighted average of the plurality of unaccounted bin-level cell voltage imbalances.

19. The system of claim 18, wherein building a machine learning model to predict bin-level cell voltage imbalance of each bin, based on bin parameters defined, comprises:
preprocessing the bin parameters of each bin to determine vehicle condition parameters corresponding to the bin, wherein the vehicle condition parameters are one or more vehicle parameters representing operation status of the target vehicle;
training a Random Forest model to map the vehicle condition parameters to the observed bin-level cell voltage imbalance, wherein the RF model is configured to predict the bin-level cell voltage imbalance based on the vehicle condition parameters; and
applying the trained RF model to obtain the predicted bin-level cell voltage imbalance of the bin based on the vehicle condition parameters.

20. A computer storage medium, on which computer instructions are stored, when the computer instructions are executed by a processor of the computer, the computer is made to execute a method for detecting vehicle battery cell imbalance, the method comprising:
acquiring a plurality of raw vehicle data of a target vehicle type in a preset time period, the raw vehicle data comprising vehicle parameters of various data types of the target vehicle type;
grouping the plurality of raw vehicle data into a predefined number of bins based on the data type and the value range of raw vehicle data;
determining an observed bin-level cell voltage imbalance of the bin, wherein the observed bin-level cell voltage imbalance is an average of all observed cell voltage imbalances in the bin, and the observed cell voltage imbalance is a difference between the maximum battery cell voltage and the minimum battery cell voltage in a battery pack of the target vehicle type;
building a machine learning model to predict bin-level cell voltage imbalance of each bin, based on bin parameters defined;
determining a difference between the observed bin-level cell voltage imbalance and the predicted bin-level cell voltage imbalance of each bin, to obtain an unaccounted bin-level cell voltage imbalance; and
determining whether there is a high risk of cell imbalance in a target vehicle based on a weighted average of the plurality of unaccounted bin-level cell voltage imbalances.
